(19) United States
(12) Patent Application Publication
(10) Pub. No.: US 2011/0061707 A1
(43) Pub. Date: Mar. 17, 2011

(54) DYE-SENSITIZED SOLAR CELLS AND MOBILE DEVICE INCLUDING THE SAME

(75) Inventors: Woon-Chun KIM, Suwon-si (KR); Hyun-Seop Shim, Incheon-si (KR); Soon-Gyu Yim, Seongnam-si (KR)

(73) Assignee: SAMSUNG ELECTRO-MECHANICS CO., LTD.

(21) Appl. No.: 12/650,198

(22) Filed: Dec. 30, 2009

(30) Foreign Application Priority Data
Sep. 15, 2009 (KR) 10-2009-0086934

(51) Int. Cl. H01L 31/042

(52) U.S. Cl. 136/244

(57) ABSTRACT

A dye-sensitized solar cell and a mobile device including the same are disclosed. The dye-sensitized solar cell includes a first transparent substrate, which allows sunlight incident to pass through, a second substrate, which is formed apart from the first substrate, and a plurality of cells, which includes a first electrode, a second electrode, a light absorption layer and an electrolyte. Here, the first electrode and the second electrode are interposed between the first substrate and the second substrate, the first electrode is disposed on a rear surface of the first substrate, the second electrode is disposed on a front surface of the second substrate, the light absorption layer is interposed between the first electrode and the second electrode and includes metal oxide and a dye absorbed in the metal oxide, and the electrolyte is interposed between the first electrode and the second electrode.

### CROSS-REFERENCE TO RELATED APPLICATIONS

This application claims the benefit of Korean Patent Application No. 10-2009-0086948, filed with the Korean Intellectual Property Office on Sep. 15, 2009, the disclosure of which is incorporated herein by reference in its entirety.

### BACKGROUND

1. Technical Field

The present invention relates to a dye-sensitized solar cell and a mobile device including the same.

2. Description of the Related Art

A silicon solar cell is generally used in a mobile device such as a mobile phone. However, since such silicon solar cell uses a silicon wafer, it is vulnerable to shocks.

Furthermore, since the silicon solar cell uses a silicon wafer, the cell becomes thick, and thus a mobile device using the silicon solar cell also becomes thick. This leads to a less aesthetically pleasing appearance, causing inconvenience to a user.

Also, since the silicon solar cell itself has a limited choice of colors, the aesthetic appearance of the silicon solar cell is deteriorated when viewed from the outside.

Also, since the manufacturing process of a silicon solar cell includes a dry thin-film process, the manufacturing cost is relatively higher.

To solve these problems, there has been an increased demand for the development of a new type of solar cell that can be used in a mobile device.

### SUMMARY

The present invention provides a dye-sensitized solar cell that is inexpensive to manufacture, is not vulnerable to shocks, is thin and is aesthetically attractive, and a mobile device including the same.

An aspect of the present invention provides a dye-sensitized solar cell that includes a first substrate, which allows a ray of sunlight incident from the front to pass through and in which the first substrate is transparent, a second substrate, which is formed apart from the first substrate and in which the second substrate faces the first substrate, and a plurality of cells, which includes a first electrode, a second electrode, a light absorption layer and an electrolyte. Here, the first electrode and the second electrode are interposed between the first substrate and the second substrate, the first electrode is disposed on a rear surface of the first substrate, the second electrode is disposed on a front surface of the second substrate, the light absorption layer is interposed between the first electrode and the second electrode and includes metal oxide and a dye absorbed in the metal oxide, and the electrolyte is interposed between the first electrode and the second electrode. Each of the plurality of cells has a specific shape, size and color when viewed from the front, and a voltage equal to or greater than a particular size is generated by connecting the plurality of cells to one another.

The plurality of cells can be serially connected to one another.

The plurality of cells can be connected to one another in parallel.

Another aspect of the present invention provides a mobile device that includes a body and the above dye-sensitized solar cell, which is mounted on the body.

A voltage generated by connecting the plurality of cells to one another in the dye-sensitized solar cell can be equal to or greater than a minimum voltage required to operate the mobile device.

Additional aspects and advantages of the present invention will be set forth in part in the description which follows, and in part will be obvious from the description, or may be learned by practice of the invention.

### BRIEF DESCRIPTION OF THE DRAWINGS

FIGS. 1 and 2 briefly show a mobile device including a dye-sensitized solar cell in accordance with an embodiment of the present invention.

FIG. 3 is a front view briefly illustrating a portion of a dye-sensitized solar cell in accordance with an embodiment of the present invention.

FIG. 4 is a cross-sectional view briefly illustrating a transversal line IV-IV of FIG. 3.

FIG. 5 briefly shows a structure of a dye-sensitized solar cell in accordance with another embodiment of the present invention.

### DETAILED DESCRIPTION

Certain embodiments of the present invention will be described below in more detail with reference to the accompanying drawings. Those components that are the same or are in correspondence are rendered the same reference numeral regardless of the figure number, and redundant descriptions are omitted.

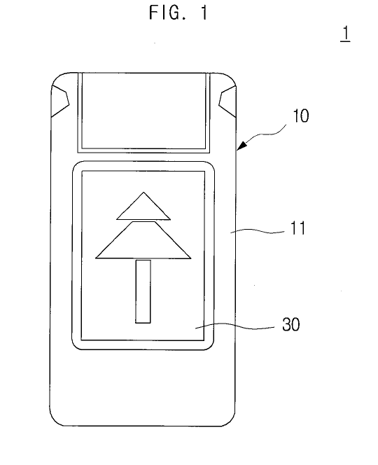

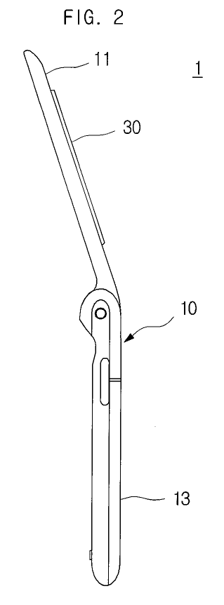

FIGS. 1 and 2 briefly show a mobile device including a dye-sensitized solar cell in accordance with an embodiment of the present invention. Here, the mobile device is illustrated as a mobile phone. However, the present invention is not limited to this example, and a variety of mobile devices, such as PMPs, PDPs and laptop computers, can be provided with the present invention.

Below, it shall be assumed that a mobile device according to the present embodiment is a mobile phone.

Referring to FIGS. 1 and 2, a mobile phone 1 according to the present embodiment can be constituted by a body 10 and a dye-sensitized solar cell 30, which is mounted on the body 10. The body 10 includes a front body 11 and a rear body 13, which are equipped with various electronic components (not shown). The dye-sensitized solar cell 30 supplies electric power to the body 10, and can be coupled to, for example, the front surface of the front body 11.

In this embodiment, by mounting the dye-sensitized solar cell 30 rather than a silicon solar cell, which includes a silicon wafer, on the body 10 of the mobile phone 1, the dye-sensitized solar cell 30 is less vulnerable to shocks, the entire mobile phone 1 becomes thin, and it is inexpensive to manufacture the mobile phone 1.

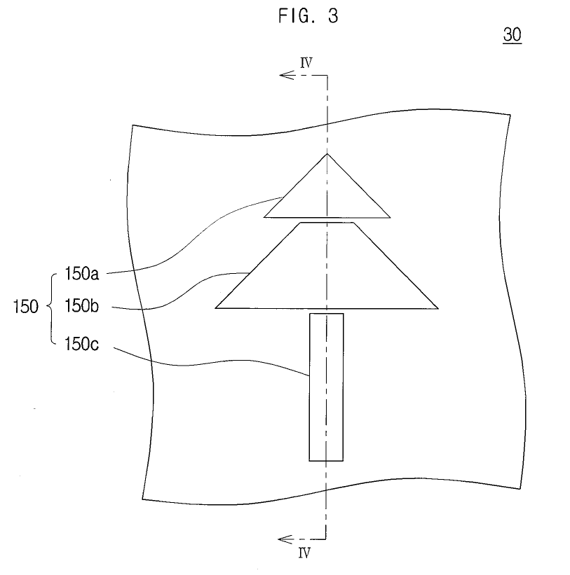

FIG. 3 is a front view briefly illustrating a portion of a dye-sensitized solar cell in accordance with an embodiment of the present invention. Referring to FIG. 3, the dye-sensitized solar cell 30 according to the present embodiment can be constituted by a plurality of cells 150, each of which has a particular shape, size and color.

When viewed from the front, a particular picture can be completed by combining the plurality of cells 150. Here, the particular picture is a picture that is predetermined to provide aesthetic attractiveness to the user before the dye-sensitized solar cell 30 is manufactured. For example, the particular picture can be a tree, as shown in FIG. 3.

To complete such particular picture, the plurality of cells 150, each of which forms a portion of the particular picture, can have a particular shape, size and color. For example, if it is assumed that the picture of a tree is completed by using three cells, as in the example illustrated in FIG. 3, a first cell 150a and a second cell 150b can form the leaves of the tree, and a third cell 150c can form the trunk of the tree.

In this case, the size and shape of the first cell 150a, the second cell 150b and the third cell 150c can be as those shown in FIG. 3, while the color of the first cell 150a and the second cell 150b can be green, and the color of the third cell 150c can be brown.

As such, the dye-sensitized solar cell according to the present embodiment can provide aesthetic attractiveness to the user by completing a particular picture through a combination of the plurality of cells 150, each of which has a particular shape, size and color, in addition to generating electric power.

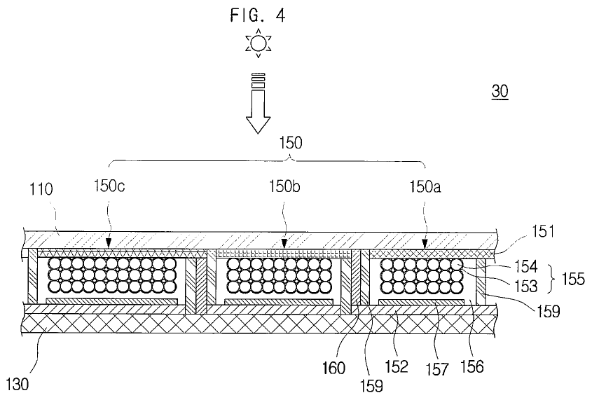

FIG. 4 is a cross-sectional view briefly illustrating a transversal line IV-IV of FIG. 3. Referring to FIG. 4, the configuration and structure of the dye-sensitized solar cell 30 according to the present embodiment will be described hereinafter.

The dye-sensitized solar cell 30 of the present embodiment can be constituted by a first substrate 110, a second substrate 130 and the plurality of cells 150.

The first substrate 110 is transparent and can allow a ray of sunlight being incident from the front to pass through. The first substrate 110 can be made of glass or high polymer such as PET.

The second substrate 130 supports another part of the dye-sensitized solar cell 30 and is formed apart from the first substrate 110, allowing a gap from the first substrate 110. The second substrate 130 can be made of glass, metal, ceramic or high polymer such as PET.

The plurality of cells 150 can be disposed between the first substrate 110 and the second substrate 130. Although FIG. 4 shows three cells 150, the number of cells is not limited to what is presented in this embodiment.

Referring to FIG. 4, the first cell 150a, the second cell 150b and the third cell 150c are disposed in parallel to one another between the first substrate 110 and the second substrate 130.

The structure of the first cell 150a will be described hereinafter, and the description of the second cell 150b and the third cell 150c, each of which has the same structure as that of the first cell 150a, will be omitted. In this case, the reference numerals that are used for the configuration of the first cell 150a will be used for the configurations of the second cell 150b and the third cell 150c, each of which has the same configuration as that of the first cell 150a.

The first cell 150a can be constituted by a first electrode 151, a second electrode 152, a light absorption layer 155 and an electrolyte 156.

The first electrode 151 can be formed on a rear surface of the first substrate 110. The second electrode 152 can be formed on a front surface of the second substrate 130. The first electrode 151 and the second electrode 152 can each be formed by including Indium Tin Oxide (ITO), Fluorine-doped Tin Oxide (FTO), Carbon Nano Tube (CNT) or Graphene. The first electrode 151 and the second electrode 152 each has conductivity and can be transparent.

A catalytic layer 157 can be formed on a front surface of the second electrode 152. The catalytic layer 157 can be formed by including platinum (Pt), carbon, CNT or Graphene. The catalytic layer 157 can be formed on a rear surface of the first electrode 151, depending on the position of the light absorption layer 155, which will be described later.

The light absorption layer 155 can be formed on a rear surface of the first electrode 151. The light absorption layer 155 can be formed by including metal oxide 153 and a dye 154, which is absorbed into the metal oxide 153. When the sunlight is absorbed in the dye 154, the dye 154 transfers electrons from a ground state to an excited state. The excited state electron is injected into a conduction band of an interface between metal oxide particles, and the injected electron is transferred to the first electrode 151 along the interface between metal oxide particles and is moved to the second electrode 152, which is electrically connected with the first electrode 151.

The dye, which is oxidized as a result of electronic transition, can be deoxidized by an iodine oxidation-reduction pair (I₃⁻/I⁻) in an electrolyte 156, which will be described later. The oxidized iodine oxidation-reduction pair makes a reduction reaction with electrons arrived at an interface of the second electrode 152 to achieve charge neutrality so that the dye-sensitized solar cell 30 can be operated.

In this embodiment, the dye 154 included in the light absorption layer 155 has a specific color. Such color of the dye 154 becomes a peculiar color of the first cell 150a when viewed from the front. Furthermore, since a wavelength region of sunlight being absorbed varies according to the color of the dye 154, the amount of electrons generated by the dye 154 can vary, depending on the wavelength region of the sunlight absorbed into the dye 154.

The light absorption layer 155 can be formed on the front surface of the second electrode 151.

Meanwhile, the electrolyte 156 can be interposed between the first electrode 151 and the second electrode 152. The electrolyte 156 can be made of an iodine oxidation-reduction liquid electrolyte, that is, an electrolyte aqueous solution of I₃⁻/I⁻ in which 1-vinyl-3-methyl-immidazolium iodide, 0.1 mol LiI, 40 m-molI₂ (iodine) and 0.2 mol tert-butyl pyridine are dissolved in 3-methoxypropionitrile. However, the electrolyte 156 is not limited to this example.

The electrolyte 156 can be sealed by a partition wall 159 that is interposed between the first electrode 151 and the second electrode 152. The partition wall 159 can be made of, for example, a thermoplastic high polymer membrane such as Surlyn, and can have a thickness of about 30˜50 μm and a width of about 1˜4 mm.

By this partition wall 159, a border of the first cell 150a can be formed. This determines a peculiar shape and size of the first cell 150a that can be recognized when viewed from the front.

The first cell 150a, the second cell 150b and the third cell 150c each has a specific shape, size and color. In this case, the voltages generated from the plurality of cells 150 can be generally different from one another although they may be the same in some cases.

The dye-sensitized solar cell 30 of the present embodiment can provide a voltage of a particular size or greater by combining the plurality of cells 150, each of which generates a same or different voltage. Here, the particular size means the minimum voltage required to operate the mobile phone 1, in which the dye-sensitized solar cell 30 is used.

The size of voltage generated from the plurality of cells 150 can be calculated. Since the size of voltage generated from each cell 150 is determined by the metal oxide 153 and the electrolyte 156 by which each cell 150 is constituted, the voltage size of each cell 150 can be calculated when each cell 150 is initially designed.

The dye-sensitized solar cell 30 according to the present embodiment provides a voltage that is equal to or greater than the minimum voltage required to operate the mobile phone 1, by combining the plurality of cells 150 of which the voltage size being generated is already known.

The plurality of cells 150 being combined can be serially connected to one another. For this, as shown in FIG. 4, the first electrode 151 constituting each cell 150 can be formed a distance apart from one another. Moreover, the second electrode 152 constituting each cell 150 can also be formed a distance apart form one another.

In this case, the first electrode 151 of each cell 150 and the second electrode 152 of an adjacent cell 150 can be electrically connected to each other by, for example, a grid electrode 160. That is, the first electrode 151 of the third cell 150c can be electrically connected to the second electrode 152 of the second cell 150b, and the first electrode 151 of the second cell 150b can be electrically connected to the second electrode 152 of the first cell 150a.

The plurality of cells 150 that are serially connected to one another by the above method can provide a voltage that is equal to or greater than the minimum voltage required to operate the mobile phone 1.

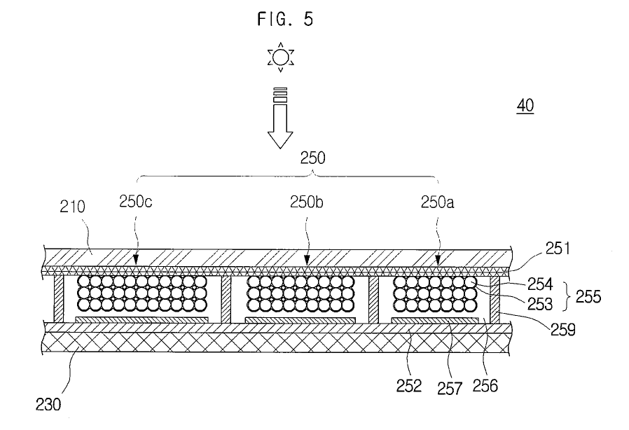

Meanwhile, the plurality of cells 150 being combined can be connected to one another in parallel. FIG. 5 briefly shows a structure of a dye-sensitized solar cell in accordance with another embodiment of the present invention. Compared to the dye-sensitized solar cell 30 according to the previously described embodiment of the present invention, a dye-sensitized solar cell 40 of the present embodiment is different in that a plurality of cells 250 are connected to one another in parallel.

Referring to FIG. 5, the plurality of cells 250 included in the dye-sensitized solar cell 40 according to the present embodiment can be connected to one another in parallel. For this, as shown in FIG. 5, a first electrode 251 constituting each cell 250 can be electrically connected to that of another cell 250. Moreover, a second electrode 252 constituting each cell 250 can also be electrically connected to that of another cell 250. The size of voltage generated from each cell 250 must be the same.

The plurality of cells 250 that are connected to one another in parallel by the above method can provide a voltage that is equal to or greater than the minimum voltage required to operate the mobile phone 1 (refer to FIG. 1).

While the plurality of cells 150 and 250 constituting the dye-sensitized solar cells 30 and 40, respectively, are connected to one another in serial or in parallel according to the previously described embodiments of the present invention, it shall be apparent that they are only some examples and the plurality of cells constituting the dye-sensitized solar cell can be connected to one another by a combination of serial and parallel connections.

While the spirit of the present invention has been described in detail with reference to particular embodiments, the embodiments are for illustrative purposes only and shall not limit the present invention. It is to be appreciated that those skilled in the art can change or modify the embodiments without departing from the scope and spirit of the present invention.

As such, many embodiments other than those set forth above can be found in the appended claims.

1. A dye-sensitized solar cell comprising:
a first substrate configured to allow a ray of sunlight incident from the front to pass through, the first substrate being transparent;
a second substrate formed apart from the first substrate, the second substrate facing the first substrate; and
a plurality of cells including a first electrode, a second electrode, a light absorption layer and an electrolyte, the first electrode and the second electrode being interposed between the first substrate and the second substrate, the first electrode being disposed on a rear surface of the first substrate, the second electrode being disposed on a front surface of the second substrate, the light absorption layer being interposed between the first electrode and the second electrode and including metal oxide and a dye absorbed in the metal oxide, the electrolyte being interposed between the first electrode and the second electrode,
wherein, each of the plurality of cells has a specific shape, size and color when viewed from the front, and a voltage equal to or greater than a particular size is generated by connecting the plurality of cells to one another.

2. The dye-sensitized solar cell of claim 1, wherein the plurality of cells are serially connected to one another.

3. The dye-sensitized solar cell of claim 1, wherein the plurality of cells are connected to one another in parallel.

4. A mobile device comprising:
a body; and
a dye-sensitized solar cell being mounted on the body in accordance with claim 1.

5. The mobile device of claim 4, wherein a voltage generated by connecting the plurality of cells to one another in the dye-sensitized solar cell is equal to or greater than a minimum voltage required to operate the mobile device.
